(19) United States
(12) Patent Application Publication
(10) Pub. No.: US 2014/0138649 A1
(43) Pub. Date: May 22, 2014

(54) ORGANIC ELECTROLUMINESCENT DEVICE

(71) Applicant: AU OPTRONICS CORP., Hsin-Chu (TW)

(72) Inventors: Chung-Chia CHEN, Hsin-Chu (TW); Yuan-Chen CHIN, Hsin-Chu (TW); Chun-Liang LIN, Hsin-Chu (TW)

(73) Assignee: AU OPTRONICS CORP., Hsin-Chu (TW)

(21) Appl. No.: 14/056,319

(22) Filed: Oct. 17, 2013

(30) Foreign Application Priority Data
Nov. 16, 2012 (TW) 101142971

(51) Int. Cl. H01L 51/52

(52) U.S. Cl. CPC H01L 51/5271; H01L 51/5275; H01L 51/5268
USPC 257/40

(57) ABSTRACT

An organic electroluminescent device comprises a substrate, a first optical structure, a transparent electrode, an organic light emitting structure, a reflecting layer and a second optical structure. The substrate has a first surface and a second surface. The first optical structure is disposed on the first surface and has a first haze. The transparent electrode is disposed on the first optical structure. The organic light emitting structure is disposed on the transparent electrode. The reflecting layer is disposed on the organic light emitting structure. The second optical structure is disposed on the second surface and has a second haze, wherein the first haze is less than the second haze.

### FIELD OF THE INVENTION

The present invention relates to an electroluminescent device and more particularly to an organic electroluminescent device with high light extraction efficiency.

### BACKGROUND OF THE INVENTION

Organic electroluminescent device, such as organic light emitting diodes (OLED), having characteristics of high brightness, rapid response time, thin and small in size, light weight, full color and providing self luminance as well as advantages of low power consumption, high luminescent efficiency, environmental friendly, and low heat emission, are considered as a next-generation display and lighting device.

Typically, an organic electroluminescent device comprises a transparent substrate, a transparent electrode (anode), a hole transport layer, an organic light emitting layer, an electron transport layer and a metal layer (cathode). When a positive bias is imposed on the organic electroluminescent device, electrons and holes are injected into the light emitting layer respectively from the cathode and the anode, and excitons are generated due to electron and hole mobility triggered by the potential difference of the external electric field, whereby light is emitted from the while portions of excitons in an excited state decay to a ground state.

However, since the organic light emitting layer has a refractive index substantially greater than that of the substrate, typically made of glass, and the refractive index of substrate is also greater than air, thus total internal reflection of light emitting from the organic light emitting layer occurs at the interfaces of these layers among the organic electroluminescent device, and mere a few light emitting from the organic light emitting layer penetrates through the glass substrate and the transparent electrode. Exemplarily, almost 80% of light emitting from the organic light emitting layer would be limited in the organic electroluminescent device. Therefore, there is a need of providing an improved organic electroluminescent device to extract the light from the organic light emitting layer more effectively to obviate the drawbacks encountered from the prior art.

### SUMMARY OF THE INVENTION

In accordance with one aspect, the present invention provides an organic electroluminescent device comprises a substrate, a first optical structure, a transparent electrode, an organic light emitting structure, a reflecting layer and a second optical structure. The substrate has a first surface and a second surface. The first optical structure is disposed on the first surface and has a first haze. The transparent electrode is disposed on the first optical structure. The organic light emitting structure is disposed on the transparent electrode. The reflecting layer is disposed on the organic light emitting structure. The second optical structure is disposed on the second surface and has a second haze, wherein the first haze is less than the second haze.

In one embodiment of the present invention, the first haze and the second haze has a numerical difference substantially greater than or equal to 10. In one embodiment of the present invention, the first haze ranges from 30% to 80%. In one embodiment of the present invention, the second haze ranges from 50% to 90%.

In one embodiment of the present invention, the second optical structure is a bulk scattering element, a surface scattering element, a micro-lens structure or the arbitrary combinations thereof.

In one embodiment of the present invention, the first optical structure is a bulk scattering element, a surface scattering element, a micro-lens structure or the arbitrary combinations thereof.

In one embodiment of the present invention, the first optical structure is a bulk scattering element comprising a composite material layer and a plurality of particles spread in the composite material layer, wherein the particles have an average diameter substantially ranging from 200 nm to 1100 nm.

In one embodiment of the present invention, the composite material layer and the particles has a refractive index difference substantially greater than 0.2.

In one embodiment of the present invention, the first optical structure is a surface scattering element comprising a plurality of particles with various diameters and a particle fixing layer used to fix the particles on the first surface of the substrate.

In one embodiment of the present invention, the organic electroluminescent device further comprises a planarization layer disposed between the surface scattering element and the transparent electrode.

In accordance with the aforementioned embodiments of the present invention, an organic electroluminescent device with high light extraction efficiency comprising a substrate, a first optical structure with a first haze, a transparent electrode, an organic light emitting structure, a reflecting layer and a second optical structure with a second haze is provided, wherein the first optical structure and the second optical structure are respectively disposed on opposite surfaces of the substrate; the transparent electrode is disposed on the first optical structure; the organic light emitting structure is disposed on the transparent electrode; the reflecting layer is disposed on the organic light emitting structure; and the first haze is less than the second haze. By optimizing the haze difference between the first optical structure and the second optical structure, a synergistic effect for extracting light emitting from the organic electroluminescent device may occur. Accordingly, the light extraction efficiency of the organic electroluminescent device can be significantly improved.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a cross-sectional view of an organic electroluminescent device in accordance with one embodiment of the present invention; and

FIG. 2 is a cross-sectional view of an organic electroluminescent device in accordance with another embodiment of the present invention.

### DETAILED DESCRIPTION OF PREFERRED EMBODIMENTS

An organic electroluminescent device with high light extraction efficiency is provided. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

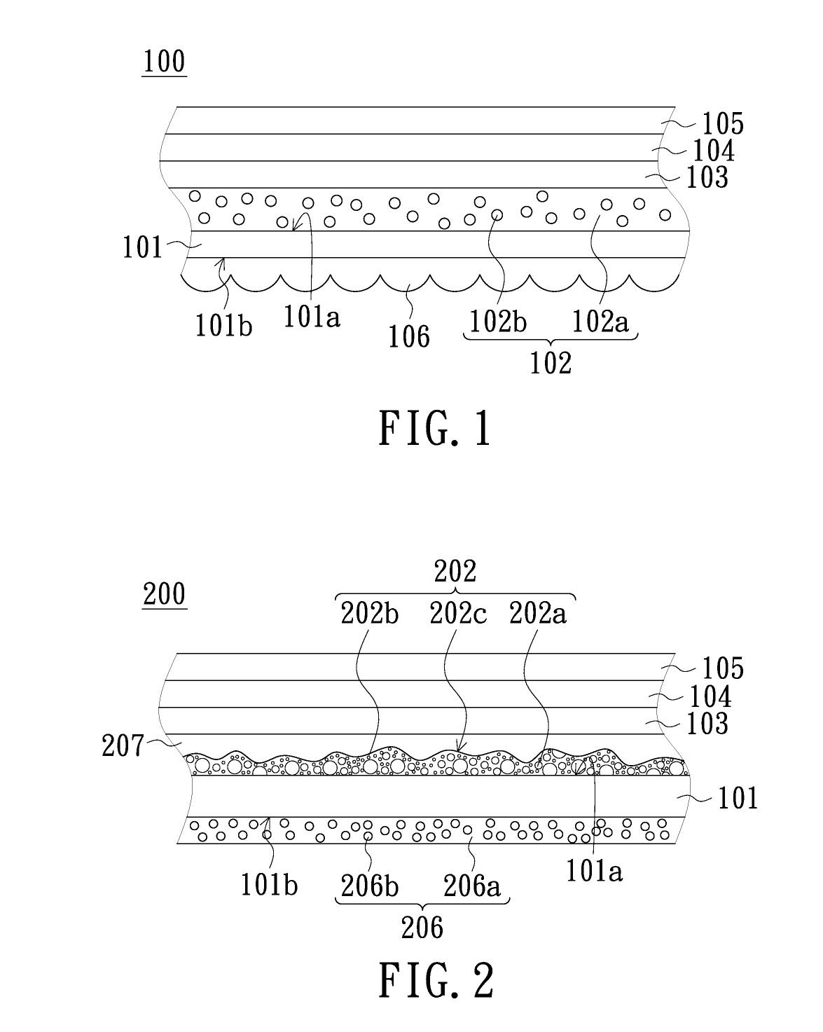

FIG. 1 is a cross-sectional view of an organic electroluminescent device 100 in accordance with one embodiment of the present invention, wherein the organic electroluminescent device 100 comprises a substrate 101, a first optical structure 102, a transparent electrode 103, an organic light emitting structure 104, a reflecting layer 105 and a second optical structure 106.

In some embodiments of the present invention, the substrate 101 is a transparent material layer preferably made of glass, semiconductor materials, plastic materials or the like. In the present embodiment, the substrate 101 is a glass substrate having a first surface 101a and a second surface 101b, wherein the first surface 101a is disposed on one side of the substrate 101 opposite to the second surface 101b.

The first optical structure 102 is disposed on the first surface 101a and has a first haze ranging from 30% to 80%. In some embodiments of the present invention, the first optical structure 102 is an inter extraction structure (IES) that may be a bulk scattering element, a surface scattering element, a micro-lens structure or the arbitrary combinations thereof.

In one embodiment of the present invention, the first optical structure 102 is a bulk scattering element comprising a composite material layer 102a and a plurality of particles 102b spread in the composite material layer 102a, wherein the composite material layer 102a is preferably made of organic polymer material, such as resin, or substrate materials having the similar properties. The particles 102b preferably are nano-particles made of titanium oxide (TiO₂), zinc oxide (ZnO), yttrium oxide (Y₂O₃), yttrium aluminum garnet (YAG), aluminum oxide (Al₂O₃), silicon dioxide (SiO₂), calcium carbonate(CaCO₃), barium sulfate (BaSO₄), zirconium dioxide (ZrO₂) or the arbitrary combinations thereof. In some embodiments of the present invention, the composite material layer 102a and the particles 102b has a refractive index difference substantially greater than 0.2, and the particles 102b have an average diameter substantially ranging from 200 nm to 1100 nm.

The first haze of the first optical structure 102 can be tuned to a level, for example ranging from 30% to 80%, by selectively altering the material and thickness of the composite material layer 102a as well as the material and the concentration of the particles 102b spread in the composite material layer 102a. In the present embodiment, the composite material layer 102a is made of a polymer and has a thickness of 1 μm, the particles 102b are TiO₂ nano-particles having an average diameter less than 500 nm and spread in the composite material layer 102a with a concentration about 6%, whereby the first haze of the first optical structure 102 can be tuned to a level substantially less than 40%, and preferably about 30%.

The transparent electrode 103 is disposed on the first optical structure 102 and preferably is a transparent indium tin oxide (ITO) anodic electrode layer. The organic light emitting structure 104 is disposed on the transparent electrode 103. In some embodiments of the present invention, the organic light emitting structure 104 at least comprises a hole injection layer (HIL), a hole transporting layer (HTL), an organic emitting layer (OEL), an electron transporting layer (ETL) and an electron injection layer (EIL). Since the physical structure of the organic light emitting structure 104 and its manufacturing method are well know by the person of ordinary skill in the art, the detailed process for fabricating the same will not be redundantly described.

The reflecting layer 105 is disposed on the organic light emitting structure 104. In some embodiments of the present invention, the reflecting layer 105 may be a metal layer or an ITO layer coating with a metal film serving as the cathode of the organic electroluminescent device 100.

The second optical structure 106 is disposed on the second surface 101b of the substrate 101 and has a second haze ranging from 50% to 90%, wherein the second haze is larger than the first haze of the first optical structure. In some embodiments of the present invention, the first haze and the second haze has a numerical difference substantially greater than or equal to 10. In some embodiments of the present invention, the second optical structure 106 is an external extraction structure (EES) comprising a bulk scattering element, a surface scattering element, a micro-lens structure or the arbitrary combinations thereof. In the present embodiment, the second optical structure 106 is a micro-lens structure having a plurality of micro-lenses with thickness about 500 μm, and each of the micro-lenses is, but not limited, a hemispherical structure having a spherical surface, an ellipsoid surface or a convex cambered surface, wherein the second haze of the second optical structure 106 is substantially greater than 85% and is preferably about 90%.

Since the emergence angle of light emitting from the organic light emitting structure 104 can be altered by the scattering of the first optical structure 102, thus total internal reflection occurring at the interfaces among the multiple materials disposed between the transparent electrode 103 (with a refractive index of 1.9) and the substrate 101 (with a refractive index of 1.5) can be decreased, and the extraction of inner light can be improved. In addition, because the second optical structure 106 has a refractive index similar to or identical with that of the substrate 101, thus total internal reflection may be unlikely to happen as light passing through the interface between the second optical structure 106 and the substrate 101. Moreover, the micro-lenses of the second optical structure 106 can direct the incident light passing through the substrate 101 emitting outward, whereby the light extraction efficiency of the organic electroluminescent device 100 can be further increased.

FIG. 2 is a cross-sectional view of an organic electroluminescent device 200 in accordance with another embodiment of the present invention, wherein the physical structure of the organic electroluminescent device 200 is similar to that of the organic electroluminescent device 100 depicted in FIG. 1, however, the first optical structure 202 and the second optical structure 206 utilized by the organic electroluminescent device 200 are different from that utilized by the organic electroluminescent device 100. For the purpose of clear description, thereinafter, the same elements are indicated by the same numbers.

In some embodiments of the present invention, the first optical structure 202 is a surface scattering element comprising a plurality of particles 202a with various diameters and a particle fixing layer 202b used to fix the particles 202a on the first surface 101a of the substrate 101 with an irregular arrangement in order to form a scattering surface 202c on the first surface 101a of the substrate 101.

In the present embodiments, the particles 202a and the particle fixing layer 202b are both made of transparent materials. The particles 202a are made of polymethylmethacrylate (PMMA), and the particle fixing layer 202b is made of polymer resin comprising PMMA.

Since the scattering surface 202c is a rough surface and the fixed particles 202a are arranged irregularly, thus light scattering occurs as light passing though the first optical structure 202, whereby the first haze of the first optical structure 202 can be controlled to rang from 30% to 80% by altering the roughness of the scattering surface 202c and the arrangement of the particles 202a.

Besides, in order to secure the transparent electrode 103 on the scattering surface 202c more tightly, a planarization layer 207 may be formed on the scattering surface 202c before the transparent electrode 103 is formed on the first optical structure 202, so as to make the planarization layer 207 disposed between the transparent electrode 103 and the first optical structure 202. Preferably, the planarization layer 207 has a refractive index identical with that of the transparent electrode 103 in order to prevent light total internal reflection occurring at the interface of the planarization layer 207 and the transparent electrode 103 which may deteriorate the light extraction efficiency of the organic electroluminescent device 200. In some embodiments of the present invention, the planarization layer 207 is formed by coating the scattering surface 202c with a layer of polymer, semi conductive material or the like that has a refractive index close to that of the material consisting of the transparent electrode 103.

The second optical structure 206 is a bulk scattering element comprising a composite material layer 206a and a plurality of particles 206b spread in the composite material layer 206a, wherein the composite material layer 206a is preferably made of organic polymer material, such as resin, or substrate materials having the similar properties. The particles 206b preferably are nano-particles made of TiO₂, ZnO, Y₂O₃, YAG, Al₂O₃, SiO₂, CaCO₃, BaSO₄, ZrO₂ or the arbitrary combinations thereof.

In some embodiments of the present invention, the composite material layer 206a and the particles 206b has a refractive index difference substantially greater than 0.2, and the particles 206b have an average diameter substantially ranging from 200 nm to 1100 nm. The second haze of the second optical structure 206 can be tuned to a level, for example ranging from 50% to 90%, by selectively altering the material and thickness of the composite material layer 206a as well as the material and the concentration of the particles 206b spread in the composite material layer 206a.

Since the emergence angle of light emitting from the organic light emitting structure 104 can be altered by the scattering of the first optical structure 202, thus total internal reflection occurring at the interfaces among the multiple materials disposed between the transparent electrode 103 (with a refractive index of 1.9) and the substrate 101 (with a refractive index of 1.5) can be decreased, and the extraction of inner light can be improved. In addition, because the emergence angle of light passing through the substrate 101 can be altered by the scattering of the bulk scattering element of the second optical structure 206, thus total internal reflection occurring at the interface between the second optical structure 206 and the external media, such as air (with a reflective index of 1), can be decreased, and the extraction of inner light can be improved, whereby the light extraction efficiency of the organic electroluminescent device 200 can be further increased.

The improvement in light extraction efficiency of the present invention can be demonstrated by multiple comparisons in light extraction among several organic electroluminescent devices. In these comparisons, the organic electroluminescent device 100, as depicted in FIG. 1, that adopt both the first optical structure 102 and the second optical structure 106 with various haze arrangements (thereinafter referred to as the experimental embodiment numbered according to the order of the measurement) are compared with the organic electroluminescent devices that neither adopt the first optical structure 102 nor the second optical structure 106 (thereinafter referred to as the first controller embodiment), and compared with the organic electroluminescent devices that merely adopt the first optical structure 102 with various haze levels (thereinafter referred to as the controller embodiment numbered according to the order of the measurement beginning from 2). In addition, the synergistic effect between the first optical structure 102 and the second optical structure 106 would be also demonstrated by these multiple comparisons.

For example, in one embodiment of the present invention, light extraction of three controller embodiments and two experimental embodiments are measured and the measured results are presented in Table 1 as shown later. Wherein the first controller embodiment is a conventional organic electroluminescent device without adopting any additional optical structure. The second and the third controller embodiments adopt the first optical structure 102 as depicted in FIG. 1, wherein the first optical structure 102 adopted by the second controller embodiment has a haze of 30%; and the first optical structure 102 adopted by the third controller embodiment has a haze of 90%. Similarly, the first and the second experimental embodiments adopt the first optical structure 102, as depicted in FIG. 1, and a transparent hemispherical structure which is much larger than the device emitting area (not shown) arranged in a manner like the second optical structure 106 does, wherein the haze of the first optical structure 102 adopted by the first experimental embodiment is about 30%, and the haze of the first optical structure 102 adopted by the second experimental embodiment is about 90%. Since the fact that the transparent hemispherical structure having high light extraction can function as the second optical structure 106 is well known to the persons skilled in the art that, thus the transparent hemispherical structure can be adopted by the experimental embodiments to take the place of the second optical structure 106, for the purpose of experimental convenience. The results of the measurement are set forth as follows:

TABLE 1

| | | The first optical | | The first optical | |
|---|---|---|---|---|---|
| | | structure | | structure | |
| | | 102 (Haze = 30%) | | 102 (Haze = 90%) | |
| | The first | The | The first | | The second |
| | con- | second | experi- | The third | experi- |
| | troller | controller | mental | controller | mental |
| | embod- | embod- | embod- | embod- | embod- |
| Samples | iment | iment | iment | iment | iment |
| The total | 1 | 1.82 x | 2.7 x | 1.95 x | 2.3x |
| light | | | | | |
| extraction | | | | | |

The total light extraction listed in Table 1 is a standardized value of the measured light extraction used to indicate the light extraction efficiency of those organic electroluminescent devices. During the data standardization, the measured light extraction of the first controller embodiment serves as a basis, thus while the total light extraction of the first controller embodiment is referred to as 1, the total light extraction of each organic electroluminescent devices is equal to the ratio of the measured light extraction of the corresponding organic electroluminescent devices to the measured light extraction of the first controller embodiment.

In other words, the second controller embodiment has 1.82 times the total light extraction of the first controller embodiment; the first experimental embodiment has 2.7 times the total light extraction of the first controller embodiment; the third controller embodiment has 1.95 times the total light extraction of the first controller embodiment; and the second experimental embodiment has 2.3 times the total light extraction of the first controller embodiment.

According to the results listed in Table 1, the light extraction efficiency of the organic electroluminescent devices that adopt the first optical structure 102 is higher than that of the conventional organic electroluminescent device adopting neither the first optical structure 102 nor the second optical structure 106, in spite of the fact that the first optical structure 102 they adopt have different haze levels (there are two haze levels in the present embodiment, one is the lower level of 30%, and the other is the higher level of 90%). In addition, the light extraction efficiency of the organic electroluminescent devices that adopt the first optical structure 102 and the transparent hemispherical structure has higher light extraction efficiency than the conventional organic electroluminescent device. It is worthy to note that when the first optical structure 102 with a lower haze level is adopted, the light extraction efficiency of the organic electroluminescent devices adopting both the first optical structure 102 and the transparent hemispherical structure 106 can be further improved. In other words, there is synergistic effect between the first optical structure 102 and the transparent hemispherical structure 106.

Subsequently, more comparisons are performed. The light extraction efficiency of two organic electroluminescent devices (referred to as the third experimental embodiment and the fourth experimental embodiment) adopting both the first optical structure 102 and the second optical structure 106, as shown in FIG. 1, are measured. In the present embodiment, the haze of the first optical structure 102 adopted by the third experimental embodiment is about 30%, the haze of the first optical structure 102 adopted by the fourth experimental embodiment is about 90%, and the second optical structures 106 adopted by the third and forth experimental embodiments has an identical haze of 90%. The results of the measurement are set forth in Table 2 as the follows :

TABLE 2

| | | The first optical | | The first optical | |
|---|---|---|---|---|---|
| | | structure 102 | | structure 102 | |
| | | (Haze = 30%) | | (Haze = 90%) | |
| | The first | The | The third | | The fourth |
| | con- | second | experi- | The third | experi- |
| | troller | controller | mental | controller | mental |
| | embod- | embod- | embod- | embod- | embod- |
| Samples | iment | iment | iment | iment | iment |
| The total | 1 | 1.82 x | 2.3 x | 1.95 x | 2.0x |
| light | | | | | |
| extraction | | | | | |

According to Table 2, the third experimental embodiment has 2.3 times the total light extraction of the first controller embodiment; and the fourth experimental embodiment has 2.0 times the total light extraction of the first controller embodiment.

In comparison the light extraction efficiency of the first, the second and the third controller embodiments, it can be observed that the organic electroluminescent devices merely adopting the first optical structure 102 either with the lower haze level (such as the second controller embodiment) or the higher haze level (such as the third controller embodiment), have an increase in light extraction efficiency substantially up to 80% higher than that of the conventional organic electroluminescent device adopting neither the first optical structure 102 nor the second optical structure 106. However, the light extraction efficiency of the organic electroluminescent devices merely adopting the first optical structure 102 is still lower than that of the organic electroluminescent devices that adopting both the first optical structure 102 and the second optical structure 106.

In the present embodiment, the organic electroluminescent devices that adopt the second optical structure 106 having a haze of 90% have about 2 times the total light extraction of the conventional organic electroluminescent device, no mater these organic electroluminescent devices further adopt the first optical structure 102 either having a haze of 30% or having a haze of 90%. Besides, the light extraction efficiency of the organic electroluminescent devices both adopting the first optical structure 102 and the second optical structure 106 is better than that of the organic electroluminescent devices merely adopting the first optical structure 102. In other words, there is synergistic effect between the first optical structure 102 and the second optical structure 106.

However, it should be appreciated that the synergistic effect between the first optical structure 102 and second optical structure 106 only occurs at certain contexts when the haze levels of the first optical structure 102 and the second optical structure 106 has a specific relation. For example, regarding to the first and the second experimental embodiments, the organic electroluminescent devices both adopting the first optical structure 102 (respectively having a lower haze level about 30% and a higher haze level about 90%) and the identical transparent hemispherical structure, respectively have 2.7 times and 2.3 times the total light extraction of the first controller embodiment. Similar results can be observed from the multiple comparisons among the first controller embodiment, the third and the fourth experimental embodiments, wherein the organic electroluminescent devices both adopting the first optical structure 102 (respectively having a lower haze level about 30% and a higher haze level about 90%) and the identical second optical structure 106 (having the second haze about 90%) respectively have 2.3 times and 2.0 times the total light extraction of the first controller embodiment. It is concluded that the light extraction efficiency of the organic electroluminescent devices may not be improved linearly along with the haze levels of the first optical structure 102, and the first optical structure 102 having the lower haze level would be more likely than the first optical structure 102 having the high level first haze to attribute the synergistic effect with the second optical structure 106 for further improving the light extraction efficiency of the organic electroluminescent devices.

In addition, the results of the multiple comparisons also indicate that the improvement in light extraction efficiency of the organic electroluminescent devices only occurs when the haze level of the first optical structure 102 is less than that of the second optical structure 106. Especially, when the haze levels of the first optical structure 102 and the second optical structure 106 have a numerical difference substantially more than 10, the synergistic effect between the first optical structure 102 and the second optical structure 106 for improving the light extraction efficiency can be manifested more significantly.

In sum, although the first optical structure 102 or the second optical structure 106 taken alone can improve the light extraction efficiency of the organic electroluminescent devices, not all combinations of the first optical structure 102 and the second optical structure 106 with arbitrary haze levels can further contribute the improvement of the light extraction efficiency. The synergistic effect between the first optical structure 102 and the second optical structure 106 merely occurs in the context when the numerical difference between the haze levels of the first optical structure 102 and the second optical structure 106 is tuned to a predetermined range.

In accordance with the aforementioned embodiments of the present invention, an organic electroluminescent device with high light extraction efficiency comprising a substrate, a first optical structure with a first haze, a transparent electrode, an organic light emitting structure, a reflecting layer and a second optical structure with a second haze is provided, wherein the first optical structure and the second optical structure are respectively disposed on opposite surfaces of the substrate; the transparent electrode is disposed on the first optical structure; the organic light emitting structure is disposed on the transparent electrode; the reflecting layer is disposed on the organic light emitting structure; and the first haze is less than the second haze. By optimizing the haze difference between the first optical structure and the second optical structure, a synergistic effect for extracting light emitting from the organic electroluminescent device may occur. Accordingly, the light extraction efficiency of organic electroluminescent device can be significantly improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An organic electroluminescent device comprising:
a substrate having a first surface and a second surface;
a first optical structure disposed on the first surface and having a first haze;
a transparent electrode disposed on the first optical structure;
an organic light emitting structure disposed on the transparent electrode;
a reflecting layer disposed on the organic light emitting structure; and
a second optical structure disposed on the second surface and having a second haze, wherein the first haze is less than the second haze.

2. The organic electroluminescent device according to claim 1, wherein the first haze and the second haze has a numerical difference substantially greater than or equal to 10.

3. The organic electroluminescent device according to claim 2, wherein the first haze ranges from 30% to 80%.

4. The organic electroluminescent device according to claim 2, wherein the second haze ranges from 50% to 90%.

5. The organic electroluminescent device according to claim 1, wherein the second optical structure is a bulk scattering element, a surface scattering element, a micro-lens structure or the arbitrary combinations thereof.

6. The organic electroluminescent device according to claim 1, wherein the first optical structure is a bulk scattering element, a surface scattering element, a micro-lens structure or the arbitrary combinations thereof.

7. The organic electroluminescent device according to claim 6, wherein the first optical structure is a bulk scattering element comprising a composite material layer and a plurality of particles spread in the composite material layer, wherein the particles have an average diameter substantially ranging from 200 nm to 1100 nm.

8. The organic electroluminescent device according to claim 7, wherein the composite material layer and the particles has a refractive index difference substantially greater than 0.2.

9. The organic electroluminescent device according to claim 6, wherein the first optical structure is a surface scattering element comprising a plurality of particles with various diameters and a particle fixing layer used to fix the particles on the first surface of the substrate.

10. The organic electroluminescent device according to claim 9, wherein the organic electroluminescent device further comprises a planarization layer disposed between the surface scattering element and the transparent electrode.
